(19) United States
(12) Patent Application Publication
(10) Pub. No.: US 2026/0239831 A1
(43) Pub. Date: Aug. 13, 2026

(54) DISPLAY SUBSTRATE AND DISPLAY DEVICE THEREOF

(71) Applicants: YUNNAN INVENSIGHT OPTOELECTRONICS TECHNOLOGY CO., LTD., Kunming (CN); BOE TECHNOLOGY GROUP CO., LTD., Beijing (CN); BEIJING BOE TECHNOLOGY DEVELOPMENT CO., LTD., Beijing (CN)

(72) Inventors: Chao PU, Beijing (CN); Dacheng ZHANG, Beijing (CN); Qingshang SHAN, Beijing (CN); Xiaochuan CHEN, Beijing (CN); Yinhu HUANG, Beijing (CN); Shengji YANG, Beijing (CN); Pengcheng LU, Beijing (CN); Zhao MA, Beijing (CN); Liuzeming QU, Beijing (CN); Qi SU, Beijing (CN); Zhuoyang XIE, Beijing (CN)

(21) Appl. No.: 19/155,839

(22) PCT Filed: Jul. 4, 2024
(86) PCT No.: PCT/CN2024/103678

§ 371 Date: Aug. 12, 2025

(30) Foreign Application Priority Data
Aug. 9, 2023 (CN) 202311001626.X

(51) Int. Cl. H10K 59/127; H10K 59/131; H10K 59/80; H10K 59/88

(52) U.S. Cl. CPC H10K 59/1275; H10K 59/131; H10K 59/871; H10K 59/88

(57) ABSTRACT

Disclosed herein are a display substrate and a related display device. The display substrate includes: a first substrate including a first region and a second region; a second substrate located on the first region of the first substrate, including a display region and a bonding region; an electrically conductive component located on at least one of the second region of the first substrate and the bonding region of the second substrate; and a sealing component located on the second region of the first substrate and on the bonding region of the second substrate, and configured to seal the conductive component. The sealing component includes a center portion and an peripheral portion at least partially surrounding the center portion. An orthogonal projection of the peripheral portion of the sealing component on the first substrate is separated from an orthogonal projection of the electrically conductive component on the first substrate.

### CROSS-REFERENCE TO RELATED APPLICATIONS

This patent application is a National Stage Entry of PCT/CN 2024/103678 filed on Jul. 4, 2024, which claims the benefit and priority of Chinese Patent Application No. 202311001626.X filed on Aug. 9, 2023, the disclosures of which are incorporated by reference herein in their entirety as part of the present application.

### TECHNICAL FIELD

Embodiments of the present disclosure relate to the field of display technology, and in particular, to a display substrate and a display device thereof.

### BACKGROUND

Organic Light-Emitting Diode (OLED) display panels have the advantages of self-illumination, high efficiency, bright colors, thinness and light weight, power saving, and a wide operating temperatures range, and have been widely used in near-eye display devices (e.g., VR or AR display devices, Electromagnetic Vortex-Flowmeter (EVF), first person view (FPV) devices, or scopes), and are gradually being applied to large area display, lighting, automotive display and so on.

### SUMMARY

Embodiments of the present disclosure provide display substrates and related display devices.

A first aspect of the present disclosure provides a display substrate. The display substrate includes: a first substrate including a first region and a second region; a second substrate located on the first region of the first substrate, the second substrate including a display region and a bonding region; a conductive component located on at least one of the second region of the first substrate and the bonding region of the second substrate; a sealing component located on the second region of the first substrate and the bonding region of the second substrate and configured to seal the electrically conductive component. The sealing component includes a center portion and a peripheral portion at least partially surrounding the center portion. The center portion has a thermal expansion coefficient closer to a thermal expansion coefficient of the electrically conductive component than the peripheral portion. An orthogonal projection of the peripheral portion of the sealing component on the first substrate is separated from an orthogonal projection of the electrically conductive component on the first substrate.

In an embodiment of the present disclosure, the peripheral portion of the sealing component has a uniform dimension in a direction parallel to the first substrate.

In an embodiment of the present disclosure, the orthogonal projection of the peripheral portion of the sealing component on the first substrate is within the first substrate.

In an embodiment of the present disclosure, the display substrate further includes: a cover plate on the display area. an orthogonal projection of the cover plate on the first substrate is separated from the orthogonal projection of the peripheral portion of the sealing component on the first substrate.

In an embodiment of the present disclosure, the cover plate has a top surface higher than the sealing component in a direction perpendicular to the first substrate.

In an embodiment of the present disclosure, an orthogonal projection of the center portion of the sealing component on the first substrate is within the orthogonal projection of the peripheral portion of the sealing component on the first substrate.

In an embodiment of the present disclosure, the display substrate further includes: an alignment mark for the cover plate disposed on the second substrate and adjacent to the cover plate. A minimum distance between the peripheral portion of the sealing component and the electrically conductive component is greater than a minimum distance between the alignment mark and the cover plate.

In an embodiment of the present disclosure, the minimum distance between the peripheral portion of the sealing component and the electrically conductive component is greater than twice the minimum distance between the alignment mark and the cover plate.

In an embodiment of the present disclosure, a minimum distance between the peripheral portion of the sealing component and the cover plate is greater than the minimum distance between the alignment mark and the cover plate.

In an embodiment of the present disclosure, the minimum distance between the peripheral portion of the sealing component and the cover plate is greater than twice the minimum distance between the alignment mark and the cover plate.

In an embodiment of the present disclosure, the electrically conductive component includes: a first pad on the bonding region of the second substrate; a second pad on the second region of the first substrate; and a lead connecting the first pad and the second pad between the first pad and the second pad.

In an embodiment of the present disclosure, the peripheral portion of the sealing component has a first portion located between the cover plate and the electrically conductive component. A minimum distance between the first portion and the cover plate is greater than a minimum distance between the first portion and the electrically conductive component.

In an embodiment of the present disclosure, the direction parallel to the first substrate includes a first direction and a second direction perpendicular to the first direction. The second pad, the first pad, and the display area are disposed in sequence in the second direction. The peripheral portion of the sealing component has a width greater than a maximum dimension of the first pad in the second direction.

In an embodiment of the present disclosure, the peripheral portion of the sealing component further includes a second portion located outside a space between the cover plate and the electrically conductive component. The second portion has a width greater than a width of the first portion and less than twice a maximum dimension of the second pad in the second direction.

In an embodiment of the present disclosure, the first pad has a maximum dimension in the second direction less than a maximum dimension of the second pad in the second direction.

In an embodiment of the present disclosure, the peripheral portion of the sealing component has a parallelogram shape. The parallelogram shape includes a first edge and a second edge disposed opposite each other in the first direction and a third edge and a fourth edge disposed opposite each other in the second direction. The first edge is adjacent to the first pad and the second edge is adjacent to the second pad. A minimum distance in the second direction between the second pad and the second edge is greater than a minimum distance in the first direction between the second pad and the third edge or the second pad and the fourth edge.

In an embodiment of the present disclosure, the minimum distance in the first direction between the second pad and the third edge is equal to the minimum distance in the first direction between the second pad and the fourth edge.

In embodiments of the present disclosure, the parallelogram shape has rounded corners. A rounded corner defined by the first edge with the third edge or the first edge with the fourth edge has a radius of curvature greater than a radius of curvature of a rounded corner defined by the second edge with the third edge or the second edge with the fourth edge.

In an embodiment of the present disclosure, a minimum distance in the first direction between the first pad and the third edge or the first pad and the fourth edge is less than a minimum distance in the second direction between the second pad and the second edge.

A second aspect of the present disclosure provides a display device. The display device including the display substrate according to any one of the embodiments in the first aspect.

Further aspects and embodiments of adaptability will become apparent from the description provided herein. It should be understood that various aspects of the present application may be implemented individually or in combination with one or more other aspects. It should also be understood that the description and specific embodiments provided herein are intended for purposes of illustration only and are not intended to limit the scope of the present application.

### BRIEF DESCRIPTION OF THE DRAWINGS

The drawings described herein are only for illustrative purposes only of the selected embodiments and not all possible implementations, and are not intended to limit the scope of the present application, in which:

FIG. 1 illustrates a top view of a display substrate;

FIG. 2 illustrates a top view of a display substrate according to an embodiment of the present disclosure;

FIG. 3 illustrates a cross-sectional view of the display substrate with an unfilled center portion along the line XX1 in FIG. 1;

FIG. 4 illustrates a cross-sectional view of the display substrate with a filled center portion along the line XX1 in FIG. 1;

FIG. 5 illustrates a cross-sectional view of the display substrate with an unfilled center portion along line YY line FIG. 2;

FIG. 6 illustrates a cross-sectional view of the display substrate with a filled center portion along line YY1 in FIG. 2;

FIG. 7 illustrates a top view of a display substrate according to another embodiment of the present disclosure;

FIG. 8 illustrates an optical microscope diagram of the display substrate of FIG. 7;

FIG. 9 illustrates an optical microscope diagram of a sealing component of the display substrate of FIG. 7; and

FIG. 10 illustrates a schematic view of a structure of a display device according to an embodiment of the present disclosure.

Corresponding reference numerals indicate corresponding parts or features throughout the several views of the accompanying drawings.

### DETAILED DESCRIPTION

Firstly, unless otherwise explicitly defined, it should be noted that the singular form of the words used in the specification and appended claims may include the plural form, and vice versa. Thus, when a term is mentioned in the singular form, it usually includes the plural form. Similarly, the words “include” and “comprise” will be interpreted as inclusive rather than exclusive. Likewise, the terms “comprise” and “or” should be interpreted as inclusive unless otherwise defined herein. Where the term “example” is used herein, and particularly following a group of terms, it is merely exemplary and illustrative and should not be considered as exclusive or extensive.

In addition, it should also be noted that, when elements of the present application and its embodiments are introduced, articles “a/an”, “one”, “that” and “the/said” are intended to indicate the presence of one or more elements; unless otherwise specified, “a plurality of” means two or more; the expressions “comprise”, “include”, “contain” and “have” are intended as inclusive and mean that there may be other elements besides those elements listed; the terms “first”, “second”, “third” and the like are just used for the purposes of description, and should not be understood as indicating or implying any relative importance or formation order.

It should be understood that when a layer, a region, or a component is referred to as being “on” another part, it means that it is directly on the other part, or there may be another component therebetween. In contrast, when a component is referred to as being “directly” on another component, it means that there is no other components therebetween. In embodiments of the present disclosure, conditions of reliability testing refer to periodically changing the operating temperature of the display substrate for a period of time in an environment with a certain level of humidity. For example, the conditions of the reliability testing may include: a humidity of 85; a low temperature of −55° C.; a high temperature of +85° C.; a transition between the low and high temperatures every half hour; and a duration of 240 hours.

Exemplary embodiments will now be described in detail with reference to the accompanying drawings.

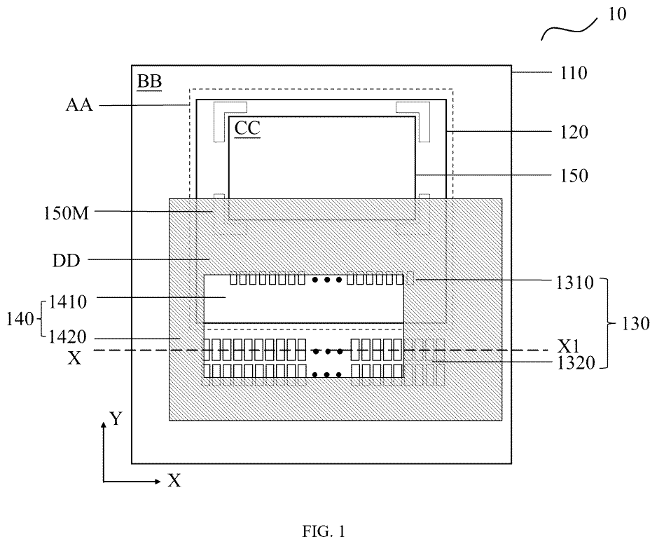

FIG. 1 illustrates a top view of a display substrate. Generally, the display substrate 10 includes a first substrate 110, a second substrate 120, an electrically conductive component 130, and a sealing component 140.

As illustrated in FIG. 1, the first substrate 110 includes a first region AA and a second region BB. The second substrate 120 is located on the first region AA of the first substrate 110. The second substrate 120 includes a display region CC and a bonding region DD. The second substrate 140 includes a monocrystalline silicon substrate. The display panel 10 further includes an organic electroluminescent display (OLED) located on the monocrystalline silicon substrate and a pixel driving circuit for driving the OLED.

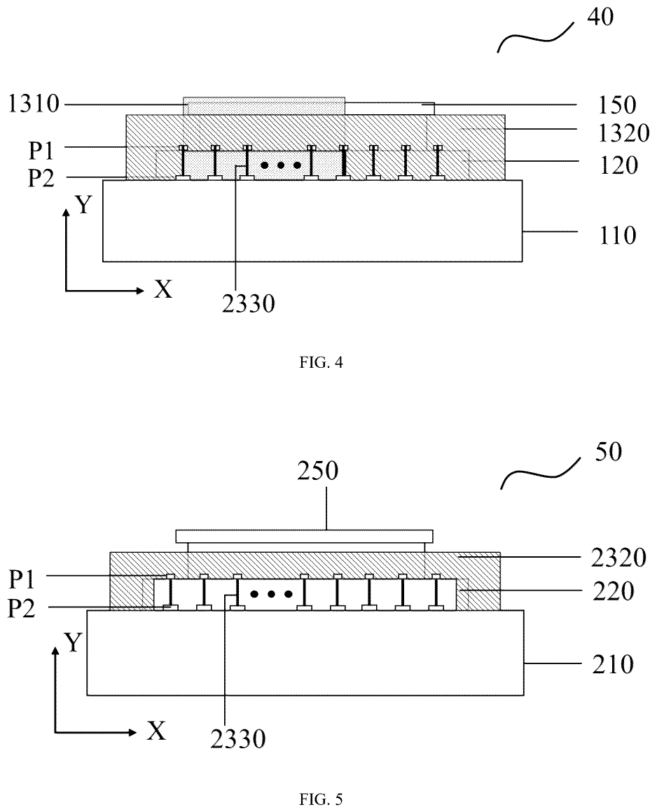

As illustrated in FIG. 1, the electrically conductive component 130 is located on at least one of the second region BB of the first substrate 110 and the bonding region DD of the second substrate 120. The electrically conductive component 130 includes a first pad 1310, a second pad 1320, and a lead 1330 (not illustrated in FIG. 1) connecting the first pad 1310 and the second pad 1320 and between the first pad 1310 and the second pad 1320. The lead 1330 will be illustrated below with reference to FIGS. 3 and 4 and will not be repeated herein.

As illustrated in FIG. 1, the sealing component 140 is located on the second region BB of the first substrate 110 and on the bonding region DD of the second substrate 120, and is configured to seal the electrically conductive component 130. The sealing component 140 includes a center portion 1410 (for clarity, the center portion 1410 is illustrated to be transparent) and a peripheral portion 1420 at least partially surrounding the center portion 1410. In the substrate 10 illustrated in FIG. 1, the center portion 1410 may include a filler adhesive and the peripheral portion 1420 may include a cofferdam adhesive. The viscosity of the peripheral portion 1420 is typically greater than the viscosity of the center portion 1410. That is, the viscosity of the cofferdam adhesive is greater than the viscosity of the filler adhesive.

In addition, the dimensions of the peripheral portion 1420 of the sealing component 140 are non-uniform in a direction parallel to the first substrate 110. As illustrated in FIG. 1, the width of edges of the peripheral portion 1420 is non-uniform. In other existing display substrates, the width may be non-uniform with respect to any edge of the peripheral portion 1420. A sealing component having such a structure may cause a broken electrical connection by uneven force on display substrate due to thermal expansion and contraction under temperature change, resulting in electrical disconnection, thereby affecting the display effect of the display substrate or shortening the life of the display substrate.

The center portion 1410 has a thermal expansion coefficient closer to the thermal expansion coefficient of the electrically conductive component 130 than the peripheral portion 1420. As illustrated in FIG. 1, the peripheral portion 1420 is in contact with the electrically conductive component 130. The peripheral portion 1420 is in contact with the first pad P1, the second pad P2, and the leads (not illustrated in FIG. 1). In other existing display substrates, the peripheral portion 1420 may be in contact with one or two of the first pad P1, the second pad P2, and the leads (not illustrated in FIG. 1).

The display substrate 10 further includes a cover plate 150 and an alignment mark 150M for the cover plate 150. The cover plate 150 is located on the display region CC of the second substrate 120. As illustrated in FIG. 1, the cover plate 150 is in contact with the peripheral portion 1420. The contact of the cover plate 150 with the peripheral portion 1420 will be described in detail below with reference to the cross-sectional views illustrated in FIGS. 3 and 4.

FIG. 3 illustrates a cross-sectional view of the display substrate with an unfilled center portion along the line XX1 in FIG. 1. FIG. 4 illustrates a cross-sectional view of the display substrate with a filled center portion along the line XX1 in FIG. 1. As illustrated in FIG. 3, in the cross-sectional view of the display substrate 30 along the line XX1 in FIG. 1, the peripheral portion 1320 of the sealing component 130 is lower than a top surface of the cover plate 150 in a direction perpendicular to the first substrate 110. As illustrated in FIG. 4, in the display substrate 40 after filling the center portion 1310 of the sealing component 130, the center portion 1310 is higher than the top surface of the cover plate 150 in the direction perpendicular to the first substrate 110. This structure results in that, when encapsulating the display substrate 10, 30, or 40, the encapsulation assembly contacts the sealing component 140 (e.g., the center portion 1410). In a direction perpendicular to the first substrate 110, the encapsulation assembly exerts a force on the sealing component 140 causing the sealing component 140 to be damaged, and to lose the sealing effect, thereby deteriorating the components of the display substrate 10, 30, or 40 in the presence of water and oxygen, and affecting the display quality and the life of the display substrate 10, 30, or 40. In addition, due to the thermal expansion and contraction effect, the peripheral portion 1420 exerts a force on the cover plate 150 in the direction parallel to the first substrate 110, which causes the loss of the encapsulation effect of the cover plate 150, thereby reducing the display quality and life of the display device encapsulated therein.

During reliability testing of this display substrate 10, since the thermal expansion coefficient (e.g., the linear thermal expansion coefficient) of the peripheral portion 1420 is much larger than the thermal expansion coefficient (e.g., the linear thermal expansion coefficient) of the electrically conductive component 130, the temperature change can cause the electrical connection between the electrically conductive components to be disrupted (i.e., resulting in wire breakage with reduced reliability). This will cause the display substrate 10 to present an abnormal display or black screen.

As described above, the contact of the peripheral portion 1420 with the electrically conductive parts 130 (the first pad P1, the second pad P2, and the lead (not illustrated in FIG. 1)) results in broken leads, which in turn causes the display substrate to present an abnormal display or a black screen. The present application provides a new display substrate that improves or enhances the display quality of the display substrate by separating a peripheral portion of the sealing component 140 from the electrically conductive component 130 to avoid broken lead, and thereby avoid the problem of the display substrate exhibiting the abnormal display or the black screen.

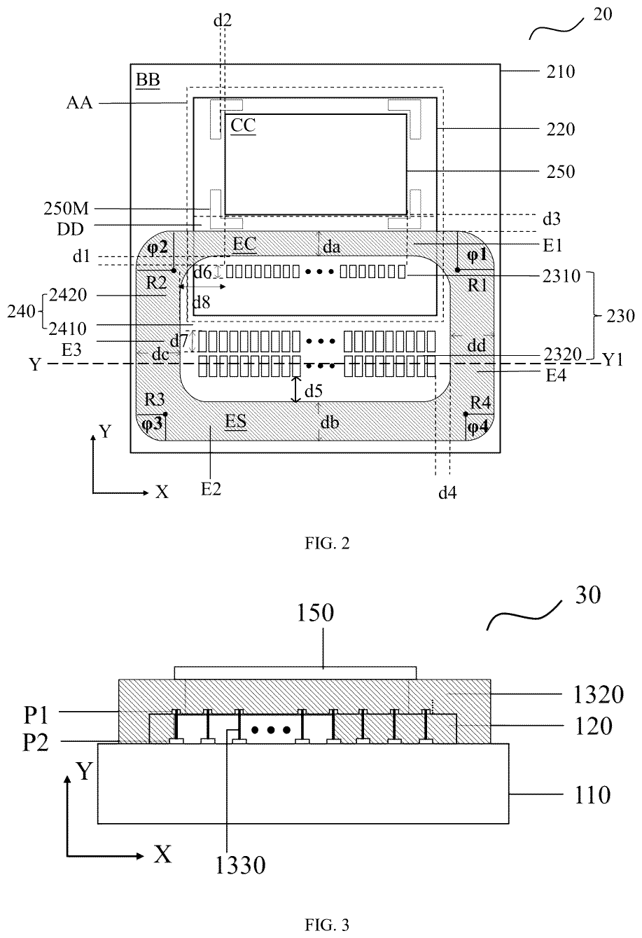

The technical solution proposed in the present application is further described below with reference to FIG. 2 and FIGS. 5 to 10.

FIG. 2 illustrates a top view of a display substrate according to an embodiment of the present disclosure. As illustrated in FIG. 2, the display substrate 20 includes a first substrate 210, a second substrate 220, an electrically conductive component 230, and a sealing component 240. The first substrate 210, the second substrate 220, the electrically conductive component 230, the sealing component 240, the cover plate 250, and the alignment mark 250M are respectively similar to the first substrate 110, the second substrate 120, the electrically conductive component 130, the sealing component 140, the cover plate 150 and the alignment mark 150M illustrated in FIG. 1.

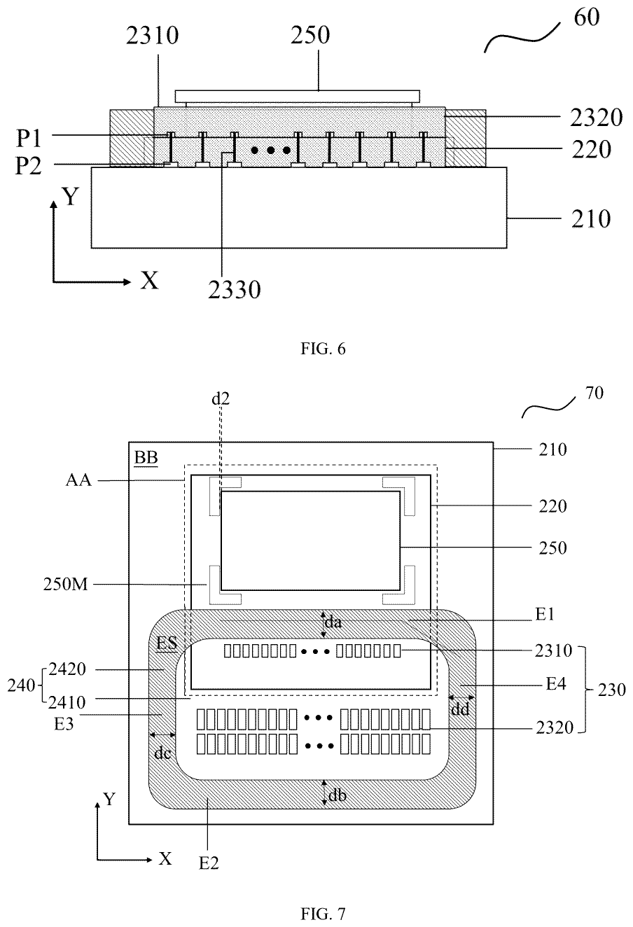

As illustrated in FIG. 2, the electrically conductive component 230 includes: a first pad 2310 on the bonding region DD of the second substrate 220; a second pad 2320 on the second region BB of the first substrate 210; and a lead 2330 (not illustrated in the FIG. 2) connecting the first pad 2310 and the second pad 2320 between the first pad 2310 and the second pad 2320. The lead 2330 will be illustrated below with reference to FIGS. 5 and 6 and will not be repeated herein. The first pad 2310 and the second pad 2320 are provided in an array. As illustrated in FIG. 2, the first pad 2310 is provided in a 1×N array, and the second pad 2320 is provided in a 2×M array. N and M are integers greater than 1. Both the first pad 2310 and the second pad 2320 include a functional pad and a dummy pad. In the first direction X, the dummy pad is disposed on both sides of the functional pad.

In an embodiment, a maximum dimension d6 of the first pad 2310 in the second direction is smaller than a maximum dimension d5 of the second pad 2320 in the second direction. As illustrated in FIG. 2, a direction parallel to the first substrate 210 includes the first direction X and a second direction Y perpendicular to the first direction X. The second pad 2320, the first pad 2310, and the display region CC are disposed in the second direction Y.

In an embodiment of the present disclosure, the orthogonal projection of the peripheral portion 2420 on the first substrate 210 may be within the first substrate 210. The orthogonal projection of the center portion 2410 on the first substrate 210 is within the orthogonal projection of the peripheral portion 2420 on the first substrate 210.

In an embodiment of the present disclosure, the center portion 2410 has a thermal expansion coefficient closer to a thermal expansion coefficient of the electrically conductive component 130 than the peripheral portion 2420. In an embodiment of the present disclosure, the first pad 2310 is configured to have a thermal expansion coefficient that is the same as or similar to a thermal expansion coefficient of the second pad 2320.

In an embodiment of the present disclosure, the center portion 2410 has a density greater than a density of the peripheral portion 2420. In an embodiment of the present disclosure, the density of the center portion 2410 is 1.5-2.0 g/cm³, and the density of the peripheral portion 2420 is 1.0-1.5 g/cm³. The host materials of the center portion 2410 and the peripheral portion 2420 include: silicone, acrylic resin, and epoxy resin. The density of the center portion 2410 and the peripheral portion 2420 may be adjusted by adjusting the mass percentage of the above three host materials. Typically, there is a correspondence relation between the density and the thermal expansion coefficient of the material. Thus, the thermal expansion coefficient may be changed by changing the density of the material.

In this embodiment, the thermal expansion coefficient of the lead 2330 (e.g., including aluminum) may be 23.2×10⁻⁶/° C. The thermal expansion coefficient of the first pad 2310 and the second pad 2320 (e.g., including copper) may be 17.5×10⁻⁶/° C. The thermal expansion coefficient of the center portion 1410 may be 15×10⁻⁶/° C. The thermal expansion coefficient of the peripheral portion 1420 may be 61×10⁻⁶/° C.

The main difference between the display substrate 20 in FIG. 2 and the display substrate 10 in FIG. 1 is that the orthogonal projection of the peripheral portion 2420 of the sealing component 240 on the first substrate 210 is separated from the orthogonal projection of the electrically conductive component 230 (e.g., the first pad P1, the second pad P2, and the leads (not illustrated in FIG. 2)) on the first substrate 210. A minimum distance d1 between the peripheral portion 2420 and the electrically conductive component 230 is greater than a minimum distance d2 between the alignment mark 250M and the cover plate 250.

In an embodiment of the present disclosure, the peripheral portion 240 may include a first portion EC located between the cover plate 240 and the electrically conductive component 230; and a second portion ES located outside a space between the cover plate 240 and the electrically conductive component 230. A minimum distance d3 between the first portion EC and the cover plate 240 is greater than the minimum distance d1 between the first portion EC and the electrically conductive component 230 (e.g., the first pad 2310). The peripheral portion 240 (the first portion EC and the second portion ES) has a width greater than a maximum dimension d6 of the first pad 2310 in the second direction Y and less than twice a maximum dimension d7 of the second pad 2320 in the second direction Y. As illustrated in FIG. 2, the maximum dimension d7 of the second pad 2320 in the second direction Y is greater than the maximum dimension d6 of the first pad 2310 in the second direction Y. In an embodiment of the present disclosure, the width of the peripheral portion 240 (the first portion EC and the second portion ES) is greater than the maximum dimension d6 of the first pad 2310 in the second direction Y and less than the maximum dimension d7 of the second pad 2320 in the second direction Y.

In an embodiment of the present disclosure, the peripheral portion 2420 may be a parallelogram shape. The peripheral portion 2420 includes a first edge E1 and a second edge E2 disposed opposite each other in the first direction X, and a third edge E3 and a fourth edge E4 disposed opposite each other in the second direction Y. The first edge E1 is adjacent to the first pad 2310, and the second edge E2 is adjacent to the second pad 2320. As illustrated in FIG. 2, the minimum distance d1 between the peripheral portion 2420 and the electrically conductive component 230 refers to a distance between the first edge E1 and the first pad 2310. In this embodiment, d2 is greater than 160 μm. In an embodiment of the present disclosure, E1 includes a first portion EC between the cover plate 250 and the electrically conductive component 230. In the display substrate 20 illustrated in FIG. 2, the first edge E1 is parallel to the cover plate 250 in the first direction X. The array of the first pad 2310 and the array of the second pad 2320 are deposited parallelly. In another embodiment of the present disclosure, the first edge E1 may be parallel to one or more of a setting direction of the cover plate 250, a set direction of the array of the first pad 2310 and a setting direction of the array the second pad 2320. In yet another embodiment of the present disclosure, the setting direction of the first edge E1 may be not parallel to the setting direction of the cover plate 250, the setting direction of the array of the first pad 2310 and the setting direction of the second pad 2320.

In other embodiments of the present disclosure, the peripheral portion 240 may not be a parallelogram shape. The peripheral portion 240 may be circular or other polygonal. For example, the peripheral portion 240 is hexagonal shape. The peripheral portion 240 includes the first portion EC disposed between the cover plate 240 and the electrically conductive component 230; and the second portion ES located in the space outside between the cover plate 240 and the electrically conductive component 230. The minimum distance d3 between the first portion EC and the cover plate 240 is greater than the minimum distance d1 between the first portion EC and the electrically conductive component 230 (e.g., the first pad 2310). The second portion ES has a width less than twice the maximum dimension d7 of the second pad 2320 in the second direction Y.

At least a portion of the peripheral portion 2420 of the sealing component 240 has a uniform dimension in a direction parallel to the first substrate 210. As illustrated in FIG. 2, a width db of the second edge E2, a width dc of the third edge E3, and a width dd of the fourth edge E4 of the peripheral portion 2420 are uniform. The width da of the first edge E1 of the peripheral portion 2420 is less than the width db of the second edge E2, the width dc of the third edge E3, and the width dd of the fourth edge E4. In this embodiment, the width of the first edge E1 is the same as the width of the first portion EC. In other embodiment of the present disclosure, the width of the first edge E1 is different from the width of the first portion EC. The width of the peripheral portion 2420 is greater than the maximum dimension d6 of the first pad 2320 in the second direction Y and less than the maximum dimension d5 of the second pad 2320 in the second direction Y. In the display substrate 20 illustrated in FIG. 2, the widths da of the first edge E1 (the width of the first portion EC), the widths db of the second edge E2, the widths dc of the third edge E3, and the widths dd of the fourth edge E4 are greater than the width d6 of the first pad 2310 in the direction Y, and smaller than the dimension d7 of the second pad P2 in the direction Y. In an embodiment of the present disclosure, the value of the width of the peripheral portion 2420 is preferably in the range of 1.5 to 2.1 mm. The other embodiments of the peripheral portion 2420 will be described below with reference to FIG. 7 and will not be repeated herein. Such a peripheral portion 2420 with a uniform width can avoid uneven stress on the first substrate 210 and the second substrate 220 of the display substrate 20 caused by thermal expansion and contraction, and avoid the resulting the broken electrical connection, thereby improving the display quality of the display substrate 20 and its life. In addition, this structure limits the range of the peripheral portion 2420 of the sealing component 240, thereby reducing the material consumption for the sealing component 240 (the peripheral portion 2420 and the center portion 2410) and improving the related production capacity.

In an embodiment of the present disclosure, the peripheral portion 2420 may be a rounded quadrilateral. As illustrated in FIG. 2, the peripheral portion 2420 is a rounded rectangle. In another embodiment of the present disclosure, the peripheral portion 2420 may also be a rounded trapezoid. The peripheral portion 2420 includes a first rounded corner φ1 defined by the first edge E1 with the third edge E3 and a second rounded corner φ2 defined by the first edge E1 with a fourth edge E4, respectively, and a third rounded corner φ3 defined by the second edge E2 with the third edge E3 and a fourth rounded corner φ4 defined by the second edge E2 with the fourth edge E4, respectively. In an embodiment of the present disclosure, the first rounded corner φ1 has a radius of curvature R1 larger than a radius of curvature R3 of the third rounded corner φ3 and a radius of curvature R4 of the fourth rounded corner φ4. The second rounded corner φ2 has a radius of curvature R2 also larger than the radius of curvature R3 of the third rounded corner φ3 and the radius of curvature R4 of the fourth rounded corner φ4. In the display substrate 20 illustrated in FIG. 2, the radius of curvature R1 of the first rounded corner φ1 is the same as the radius of curvature R2 of the second rounded corner φ2, i.e., R1=R2. The radius of curvature R3 of the third rounded corner φ3 is the same as the radius R4 of curvature of the fourth rounded corner φ4, i.e., R3=R4. The radius of curvature R1 of the first rounded corner φ1, the radius of curvature R2 of the second rounded corner φ2, the radius of curvature R3 of the third rounded corner φ3 and the radius of curvature R4 of the fourth rounded corner φ4 satisfy the following condition: (R1=R2)>(R3=R4). In another embodiment of the present disclosure, the radius of curvature R1 of the first rounded corner φ1 is different from the radius of curvature R2 of the second rounded corner φ2, and the radius of curvature R3 of the third rounded corner φ3 is different from the radius of curvature R4 of the fourth rounded corner φ4. The peripheral portion 2420 with this configuration can avoid the adhesion failure between the first substrate 210 and the second substrate 220 due to the concentrated stress caused by the rapid curing of the peripheral portion 2420 during the manufacturing process of the peripheral portion 2420.

The orthogonal projection of the peripheral portion 2420 on the first substrate 210 is separated from the orthogonal projection of the cover plate 250 on the first substrate 210. This structure can ensure that the sealing component 240 does not exert a force on the cover plate 250 in a direction parallel to the first substrate 210, which in turn prevents failure of the cover plate encapsulation. As illustrated in FIG. 2, the minimum distance d3 between the peripheral portion 2420 and the cover plate 250 is greater than the minimum distance d2 between the alignment mark 250M and the cover plate 250. In some embodiments of the present disclosure, the minimum distance d3 between the peripheral portion 2420 and the cover plate 250 is greater than the minimum distance d2 between the alignment mark 250M and the cover plate 250 and the minimum distance d1 between the peripheral portion 2420 and the conductive component 230. This structure can limit the range of the peripheral portion 2420 of the sealing component 240 while avoiding wire breakage with reduced reliability and encapsulation failures caused by the cover plate, thereby reducing the material consumption for the sealing component 240 and improving the related production capacity. In an embodiment of the present disclosure, the minimum distance d3 refers to a distance between the first portion EC of the first edge E1 and the cover plate 250. In an embodiment of the present disclosure, the minimum distance d3 between the peripheral portion 2420 and the cover plate 250 is greater than twice the minimum distance d2 between the alignment mark 250M and the cover plate 250. For example, the minimum distance d3 between the peripheral portion 2420 and the cover plate 250 may be greater than 160 μm.

In the direction parallel to the first substrate 210, the distance d4 between the second pad 2320 and the third edge E3 or between the second pad and the fourth edge E4 of the peripheral portion 2420 is greater than the distance d5 between the second pad 2320 and the second edge E2 of the peripheral portion 2420. As described above, in the first pad 2310 and the second pad 2320, in the first direction X, the dummy pads are disposed on both sides of the functional pad. Comparatively, the peripheral portion 2420 of the sealing component 240 (e.g., the cofferdam adhesive) has less effect on the dummy pad than on the functional pad. Thus, this structure may further limit the range of the peripheral portion 2420, which in turn reduces the material consumption for the sealing component 240 and improves the related capacity. Additionally, this structure may limit the width of the sealing portion 2420 in the first direction X, thereby reserving a sufficient space for assemblies of the entire device. alternatively, the size of the entire device can be reduced while the space for the assemblies of the entire device is constant.

As illustrated in FIG. 2, the distance between the second pad 2320 and the third edge E3 is equal to the distance between the second pad 2320 and the fourth edge E4, both of which are indicated by d4, and the distance between the second pad 2320 and the second edge E2 is indicated by d5. In an embodiment of the present disclosure, d4 is less than d5. The distance between the first pad 2310 and the third edge E3 is equal to the distance between the first pad 2310 and the fourth edge E4, both of which are indicated by d8. In an embodiment of the present disclosure, d8 is less than d5.

In an embodiment of the present disclosure, the top surface of the cover plate 250 is higher than the sealing component 240 in the direction parallel to the first substrate 210. The contact of the cover plate 250 with the peripheral portion 2420 will be described in detail below with reference to the cross-sectional views illustrated in FIGS. 5 and 6.

FIG. 5 illustrates a cross-sectional view of the display substrate with an unfilled center portion along the line YY line FIG. 2. FIG. 6 illustrates a cross-sectional view of the display substrate with a filled center portion along the line YY1 in FIG. 2. In a direction perpendicular to the first substrate 210, the peripheral portion 2320 of the sealing component 230 is lower than the top surface of the cover plate 250. As illustrated in FIG. 5, in the cross-sectional view of the display substrate 500 along the line YY1 in FIG. 2, the peripheral portion 2320 of the sealing component 230 is lower than the bottom surface of the cover plate 250. In another embodiment of the present disclosure, the peripheral portion 2320 of the sealing component 230 may be higher than the bottom surface of the cover plate 250 but lower than the top surface of the cover plate 250. In the direction perpendicular to the first substrate 210, the center portion 2310 of the sealing component 230 is also lower than the top surface of the cover plate 250. As illustrated in FIG. 6, in the display substrate 60 with the filled the center portion 2310 of the sealing component 130, the center portion 2310 is lower than the bottom surface of the cover plate 250 in the direction perpendicular to the first substrate 210. In another embodiment of the present disclosure, the center portion 2310 of the sealing component 230 is higher than the bottom surface of the cover plate 250 but lower than the top surface of the cover plate 250. This structure can avoid exerting a force on the sealing component 240 in the direction perpendicular to the first substrate 210 during the complete assembly of the display substrate 20, 50, or 60, thereby preventing the sealing component 140 from being damaged and losing its sealing function or causing the electrical connection failure, thereby improving the display quality and the life of the display substrate 20, 50, or 60.

FIG. 7 illustrates a top view of a display substrate according to another embodiment of the present disclosure. The width of the peripheral portion 2420 of the sealing component 240 is uniform in the direction parallel to the first substrate 210. As illustrated in FIG. 7, the width da of the first edge E1, the width db of the second edge E2, the width dc of the third edge E3 and the width dd of the fourth edge E4 of the peripheral portion 2420 are the same. In this embodiment, the width of the first edge E1 is the same as the width of the first portion EC. In another embodiment of the present disclosure, the width of the first edge E1 may be different from the width of the first portion EC. This structure has the same effects as the structure illustrated in FIG. 2 above in terms of improving the display quality and the life, reducing the sealing material consumption, and improving the related production capacity, and will not be repeated herein.

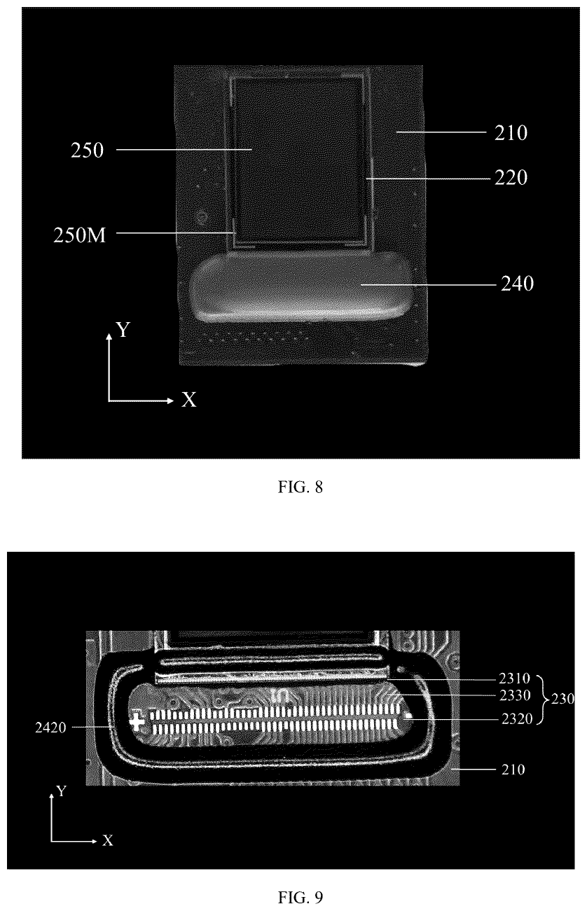

FIG. 8 illustrates an optical microscope diagram of the display substrate of FIG. 7. The center portion 2410 of the sealing component 240 has been filled. As illustrated in FIG. 8, the orthogonal projection of the sealing component 240 on the first substrate 210 is separated from the orthogonal projection of the cover plate 250 on the first substrate 210, as described above.

FIG. 9 illustrates an optical microscope diagram of the sealing component of the display substrate of FIG. 7. The center portion 2410 of the sealing component 240 has not been filled. As illustrated in FIG. 9, the orthogonal projection of the peripheral portion 2420 of the sealing component 240 on the first substrate 210 is separated from the orthogonal projection of the electrically conductive component 230 (first pad 2310, second pad 2320, and lead 2330) on the first substrate 210, as described above.

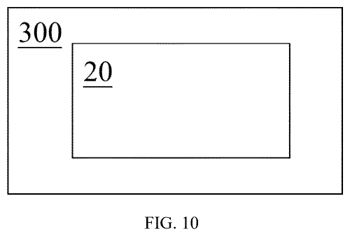

FIG. 10 illustrates a schematic structure of a display device according to embodiments of the present disclosure. As illustrated in FIG. 10, the display device 300 may include a display substrate 20, 50, or 60 as described in accordance with any embodiment of the present disclosure.

The display device 300 may be any product or component with a display function used for a VR or AR display device, an EVF, a scope, an FPV device, a phone, a tablet computer, a television, a monitor, a laptop computer, a digital photo frame, a navigator, and the like.

The display device provided by the embodiment of the present disclosure has the same or similar beneficial effects as the display substrates provided by the previous embodiments of the present disclosure. Since the display substrate has been described in detail in the previous embodiment, the description of that will be omit.

The foregoing description of the embodiment has been provided for the purpose of illustration and description. It is not intended to be exhaustive or to limit the application. The respective elements or features of a particular embodiment are generally not limited to a particular embodiment, but when it's appropriate, these elements or features are interchangeable and can be used in a selected embodiment, even if not specifically shown or described. The same can also be changed in many ways. Such changes are not to be considered a departure from this application, and all such modifications are included within the scope of this application.

1. A display substrate comprising:
a first substrate comprising a first region and a second region;
a second substrate located on the first region of the first substrate, the second substrate comprising a display region and a bonding region;
an electrically conductive component located on at least one of the second region of the first substrate and the bonding region of the second substrate; and
a sealing component located on the second region of the first substrate and on the bonding region of the second substrate, and configured to seal the electrically conductive component,
the sealing component comprising a center portion and an peripheral portion at least partially surrounding the center portion,
wherein the center portion has a thermal expansion coefficient closer to a thermal expansion coefficient of the electrically conductive component than the peripheral portion, and
wherein an orthogonal projection of the peripheral portion of the sealing component on the first substrate is separated from an orthogonal projection of the electrically conductive component on the first substrate.

2. The display substrate according to claim 1, wherein at least a portion of the peripheral portion of the sealing component has a uniform dimension in a direction parallel to the first substrate.

3. The display substrate according to claim 1, wherein the orthogonal projection of the peripheral portion of the sealing component on the first substrate is within the first substrate.

4. The display substrate according to claim 1 further comprising: a cover plate on the display area, wherein an orthogonal projection of the cover plate on the first substrate is separated from the orthogonal projection of the peripheral portion of the sealing component on the first substrate.

5. The display substrate according to claim 3, wherein the cover plate has a top surface higher than the sealing component in a direction perpendicular to the first substrate.

6. The display substrate according to claim 1, wherein an orthogonal projection of the center portion of the sealing component on the first substrate is within the orthogonal projection of the peripheral portion of the sealing component on the first substrate.

7. The display substrate according to claim 4 further comprising:
an alignment mark for the cover plate disposed on the second substrate and adjacent to the cover plate,
wherein a minimum distance between the peripheral portion of the sealing component and the electrically conductive component is greater than a minimum distance between the alignment mark and the cover plate.

8. The display substrate according to claim 7, wherein the minimum distance between the peripheral portion of the sealing component and the electrically conductive component is greater than twice the minimum distance between the alignment mark and the cover plate.

9. The display substrate according to claim 7, wherein a minimum distance between the peripheral portion of the sealing component and the cover plate is greater than the minimum distance between the alignment mark and the cover plate.

10. The display substrate according to claim 9, wherein the minimum distance between the peripheral portion of the sealing component and the cover plate is greater than twice the minimum distance between the alignment mark and the cover plate.

11. The display substrate according to claim 7, wherein the electrically conductive component comprises: a first pad on the bonding region of the second substrate; a second pad on the second region of the first substrate; and a lead connecting the first pad and the second pad between the first pad and the second pad.

12. The display substrate according to claim 11, wherein the peripheral portion of the sealing component has a first portion located between the cover plate and the electrically conductive component, and wherein a minimum distance between the first portion and the cover plate is greater than a minimum distance between the first portion and the electrically conductive component.

13. The display substrate according to claim 12, wherein the direction parallel to the first substrate comprises a first direction and a second direction perpendicular to the first direction, and wherein the second pad, the first pad, and the display area are disposed in sequence in the second direction, the peripheral portion of the sealing component having a width greater than a maximum dimension of the first pad in the second direction.

14. The display substrate according to claim 13, wherein the peripheral portion of the sealing component further comprises a second portion located outside a space between the cover plate and the electrically conductive component, the second portion having a width greater than a width of the first portion and less than twice a maximum dimension of the second pad in the second direction.

15. The display substrate according to claim 11, wherein the first pad has a maximum dimension in the second direction less than a maximum dimension of the second pad in the second direction.

16. The display substrate according to claim 15, wherein the peripheral portion of the sealing component has a parallelogram shape which comprises a first edge and a second edge disposed opposite each other in the first direction, and a third edge and a fourth edge disposed opposite each other in the second direction, wherein the first edge is adjacent to the first pad, and the second edge is adjacent to the second pad, and wherein a minimum distance in the second direction between the second pad and the second edge is greater than a minimum distance in the first direction between the second pad and the third edge or the second pad and the fourth edge.

17. The display substrate according to claim 16, wherein the minimum distance in the first direction between the second pad and the third edge is equal to the minimum distance in the first direction between the second pad and the fourth edge.

18. The display substrate according to claim 16, wherein the parallelogram shape has rounded corners, wherein a rounded corner defined by the first edge with the third edge or the first edge with the fourth edge has a radius of curvature greater than a radius of curvature of a rounded corner defined by the second edge with the third edge or the second edge with the fourth edge.

19. The display substrate according to claim 18, wherein a minimum distance in the first direction between the first pad and the third edge or the first pad and the fourth edge is less than a minimum distance in the second direction between the second edge and the second edge.

20. A display device comprising the display substrate according to claim 1.
